(19) United States
(12) Patent Application Publication
(10) Pub. No.: US 2022/0016731 A1
(43) Pub. Date: Jan. 20, 2022

(54) LASER PROCESSING METHOD

(71) Applicant: DISCO CORPORATION, Tokyo (JP)

(72) Inventor: Keiji Nomaru, Tokyo (JP)

(21) Appl. No.: 17/448,945

(22) Filed: Sep. 27, 2021

Related U.S. Application Data
(62) Division of application No. 16/130,427, filed on Sep. 13, 2018.

(30) Foreign Application Priority Data
Sep. 14, 2017 (JP) 2017-176632

(51) Int. Cl. B23K 26/082; B23K 26/06; H01L 21/82; H01L 21/683; H01L 21/687; B23K 26/70; H01L 21/78

(52) U.S. Cl. CPC B23K 26/0821; B23K 26/0643; B23K 26/0665; H01L 21/82; H01L 2221/68327; H01L 21/68714; B23K 26/704; H01L 21/78; H01L 21/6836

(57) ABSTRACT

A laser processing method for processing a wafer using a laser processing apparatus, where the laser processing apparatus includes a holding unit, a laser oscillator for emitting a pulsed laser beam, a polygon mirror for dispersing the pulsed laser beam emitted from the laser oscillator, a condenser for condensing the pulsed laser beam dispersed by the polygon mirror and applying the condensed pulsed laser beam to the workpiece and dispersed region adjuster for controlling a dispersed region of the pulsed laser beam, where the laser processing method includes steps of holding the workpiece on the holding unit and processing the workpiece held by the holding unit by applying the pulsed laser beam, where during processing, the dispersed region adjuster controls the dispersed region of the pulsed laser beam by causing the pulsed laser beam to follow a direction in which the mirror facets of the polygon mirror are rotated.

### CROSS-REFERENCE TO RELATED APPLICATIONS

This application is a divisional of and claims priority to U.S. patent application Ser. No. 16/130,427 filed on Sep. 13, 2018, the entire contents of which is incorporated herein by reference.

### BACKGROUND OF THE INVENTION

### Field of the Invention

The present invention relates to a laser processing apparatus that is capable of dispersing a pulsed laser beam over an appropriate region depending on the workpiece to be processed by the pulsed laser beam.

### Description of the Related Art

Wafers having a plurality of devices such as ICs (Integrated Circuits), LSI (Large Scale Integration) circuits, or the like formed in respective areas thereof by a plurality of projected dicing lines are divided by a dicing apparatus or a laser processing apparatus into individual device chips, which will be used in electric appliances such as mobile phones, personal computers, and so on.

A laser processing apparatus includes at least a chuck table for holding a workpiece thereon, a laser beam applying unit for applying a laser beam to the workpiece held on the chuck table, and a processing feed unit for processing-feeding the chuck table and the laser beam applying unit relatively to each other. There is also proposed a laser processing apparatus having a polygon mirror for avoiding recast (see, for example, Japanese Patent No. 4044539).

### SUMMARY OF THE INVENTION

However, the laser processing apparatus disclosed in Japanese Patent No. 4044539 is problematic in that since a pulsed laser beam is dispersed over a region established by the polygon mirror and applied to a workpiece, the pulsed laser beam cannot be dispersed over an appropriate region depending on the workpiece, with the result that a processed quality depending on the workpiece cannot be achieved.

It is therefore an object of the present invention to provide a laser processing apparatus that is capable of dispersing a pulsed laser beam over an appropriate region depending on the workpiece to be processed by the pulsed laser beam.

In accordance with an aspect of the present invention, there is provided a laser processing apparatus including a chuck table holding a workpiece thereon, a laser beam applying unit configured to apply a pulsed laser beam to the workpiece held on the chuck table, and a processing feed unit configured to processing-feed the chuck table and the laser beam applying unit relatively along an X-axis, in which the laser beam applying unit includes a laser oscillator emitting the pulsed laser beam, a polygon mirror dispersing the pulsed laser beam emitted from the laser oscillator, a condenser condensing the pulsed laser beam dispersed by the polygon mirror and applying the condensed pulsed laser beam to the workpiece held on the chuck table, and dispersed region adjusting means disposed between the laser oscillator and the polygon mirror and controlling a dispersed region of the pulsed laser beam by causing the pulsed laser beam to follow a direction in which mirror facets of the polygon mirror are rotated.

The dispersed region adjusting means should preferably include an acousto-optic deflector, an electro-optic deflector, or a resonant scanner.

According to the present invention, the pulsed laser beam can be dispersed over an appropriate region depending on the workpiece, with the result that a processed quality depending on the workpiece can be achieved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus according to an embodiment of the present invention;

FIG. 2 is a block diagram of a laser beam applying unit of the laser processing apparatus depicted in FIG. 1;

FIG. 3 is a perspective view of a wafer supported on an annular frame by an adhesive tape;

FIG. 4A is a schematic view depicting the trajectory of a pulsed laser beam dispersed by a polygon mirror;

FIG. 4B is a schematic view depicting the trajectory of the pulsed laser beam when the polygon mirror has turned 20 degrees from the position depicted in FIG. 4A; and

FIG. 4C is a schematic view depicting the trajectory of the pulsed laser beam when the polygon mirror has further turned 20 degrees from the position depicted in FIG. 4B.

### DETAILED DESCRIPTION OF THE PREFERRED EMBODIMENT

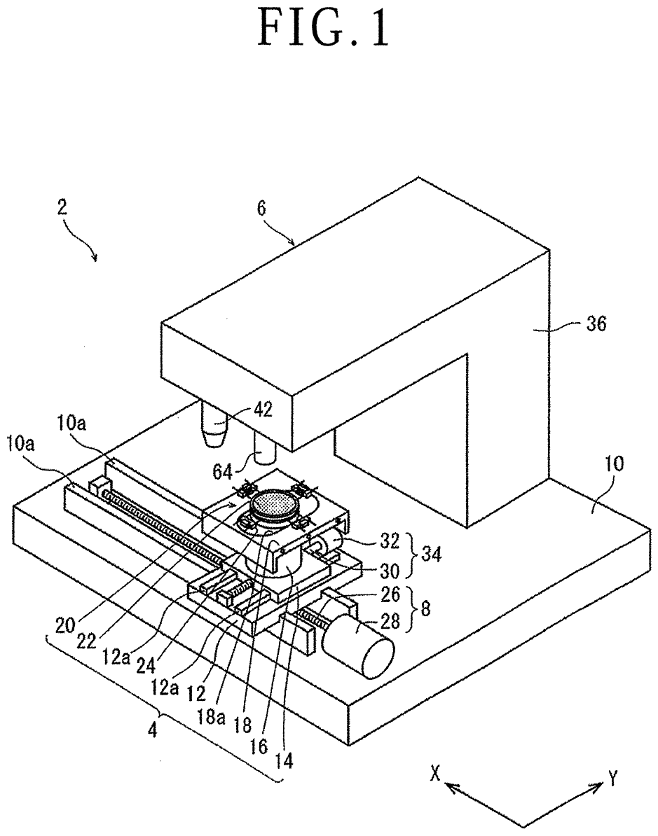

A laser processing apparatus according to an embodiment of the present invention will be described in detail below with reference to the drawings. As depicted in FIG. 1, the laser beam processing apparatus, denoted by 2, according to the present embodiment includes a holding unit 4 for holding a workpiece thereon, a laser beam applying unit 6 for applying a pulsed laser beam to the workpiece held by the holding unit 4, and a processing feed unit 8 for processing-feeding the holding unit 4 and the laser beam applying unit 6 relatively to each other along an X-axis indicated by the arrow X in FIG. 1. A Y-axis indicated by the arrow Y in FIG. 1 extends perpendicularly to the X-axis, and the X-axis and the Y-axis jointly define a substantially horizontal plane.

As depicted in FIG. 1, the holding unit 4 includes an X-axis movable plate 12 movably mounted on a base 10 for movement along the X-axis, a Y-axis movable plate 14 movably mounted on the X-axis movable plate 12 for movement along the Y-axis, a column 16 fixedly mounted on an upper surface of the Y-axis movable plate 14, and a cover plate 18 fixed to an upper end of the column 16. The cover plate 18 has an oblong hole 18a defined therein which extends along the Y-axis, and a chuck table 20 that extends upwardly through the oblong hole 18a is rotatably mounted on the upper end of the column 16. The chuck table 20 is rotatable about its own axis by rotating means, not depicted, housed in the column 16. The chuck table 20 supports on its upper surface a suction chuck 22 made of a porous material that is connected to suction means, not depicted. When the suction means is actuated to develop suction forces on an upper surface of the suction chuck 22, the chuck table 20 holds the workpiece under suction on the upper surface of the suction chuck 22. A plurality of clamps 24 are disposed on the outer circumferential edge of the chuck table 20 at circumferentially spaced intervals for holding the outer peripheral edge of the workpiece on the chuck table 20.

The processing feed unit 8 includes a ball screw 26 extending along the X-axis over the base 10 and an electric motor 28 mounted on the base 10 and coupled to an end of the ball screw 26. The ball screw 26 is threaded through a nut, not depicted, fixed to a lower surface of the X-axis movable plate 12. When the electric motor 28 is energized, it rotates the ball screw 26 about its own axis in the nut that converts the rotary motion of the ball screw 26 into straight motion and transmits the straight motion to the X-axis movable plate 12. The X-axis movable plate 12 is now moved along guide rails 10a parallel to the ball screw 26 along the X-axis, processing-feeding the chuck table 20 along the X-axis with respect to the laser beam applying unit 6. The Y-axis movable plate 14 of the holding unit 4 is movable along the Y-axis along guide rails 12a on the X-axis movable plate 12 by an indexing feed unit 34 that includes a ball screw 30 extending over the X-axis movable plate 12 along the Y-axis and threaded through a nut in the Y-axis movable plate 14 and an electric motor 32 coupled to an end of the ball screw 30. When the electric motor 32 is energized, the chuck table 20 is thus indexing-fed along the Y-axis with respect to the laser beam applying unit 6 by the indexing feed unit 34.

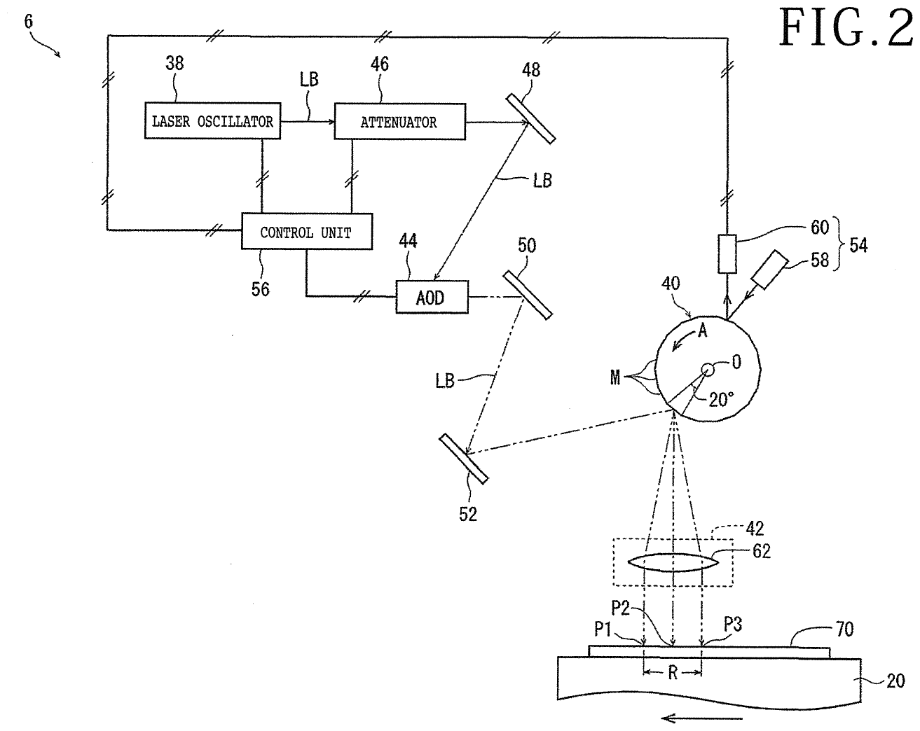

The laser beam applying unit 6 will be described below with reference to FIGS. 1 and 2. As depicted in FIG. 1, the laser beam applying unit 6 includes a frame 36 having an inverted L-shape extending upwardly from an upper surface of the base 10 and then essentially horizontally. The frame 36 houses therein, as depicted in FIG. 2, a laser oscillator 38 for emitting a pulsed laser beam LB, a polygon mirror 40 for dispersing the pulsed laser beam LB emitted from the laser oscillator 38, a condenser 42 for condensing the pulsed laser beam LB dispersed by the polygon mirror 40 and applying the condensed pulsed laser beam LB to the workpiece held by the holding unit 4, and dispersed region adjusting means 44 disposed between the laser oscillator 38 and the polygon mirror 40, for controlling a dispersed region of the pulsed laser beam LB by causing the pulsed laser beam LB to follow the direction A (see FIG. 2) in which mirror facets M of the polygon mirror 40 are rotated. Furthermore, as depicted in FIG. 2, the laser beam applying unit 6 includes an attenuator 46 for adjusting the output power of the pulsed laser beam LB emitted from the laser oscillator 38, a first mirror 48 for reflecting the pulsed laser beam LB whose output power has been adjusted by the attenuator 46 to the dispersed region adjusting means 44, a second mirror 50 and a third mirror 52 for reflecting the pulsed laser beam LB that has passed through the dispersed region adjusting means 44 to the polygon mirror 40, an angular displacement detecting unit 54 for detecting an angular displacement of the polygon mirror 40, a control unit 56, and focused spot position adjusting means, not depicted, for adjusting the vertical position of a focused spot of the pulsed laser beam LB.

The laser oscillator 38 is controlled by the control unit 56 to emit a pulsed laser beam LB having a wavelength, e.g., 355 nm, determined depending on the type of a processing process to be performed on the workpiece. The dispersed region adjusting means 44 includes either one of an AOD (Acousto-Optic Deflector), an EOD (Electro-Optic Deflector), and a resonant scanner. According to the present embodiment, the dispersed region adjusting means 44 includes an AOD and changes the angle of emission of the pulsed laser beam LB from the AOD in response to a voltage signal from the control unit 56 thereby to adjust the position where the pulsed laser beam LB falls on the polygon mirror 40, thus controlling a dispersed region of the pulsed laser beam LB, i.e., a region over which the pulsed laser beam LB is dispersed by the polygon mirror 40, by causing the pulsed laser beam LB to follow the direction A in which the mirror facets M of the polygon mirror 40 are rotated. The polygon mirror 40 has a plurality of mirror facets M (18 mirror facets each having a central angle of 20 degrees in the present embodiment) arranged on a circle around a central axis O, and is rotated about the central axis O in the direction indicated by the arrow A by a polygon mirror motor, not depicted, that is controlled by the control unit 56. The angular displacement detecting unit 54 has a light-emitting element 58 for emitting light toward the polygon mirror 40 and a light-detecting element 60 for detecting light emitted from the light-emitting element 58 and reflected by the mirror facets M of the polygon mirror 40. The light-detecting element 60 is positioned so as to detect light emitted from the light-emitting element 58 and reflected by each of the mirror facets M of the polygon mirror 40 when the mirror facet M is inclined to the light-emitting element 58 at a predetermined angle. When the light-detecting element 60 detects light, it outputs a light detection signal to the control unit 56. The condenser 42 is disposed on a lower surface of the distal end of the frame 36 (see FIG. 1), and has an fθ lens 62 (see FIG. 2) for condensing the pulsed laser beam LB that has been dispersed by the polygon mirror 40. As depicted in FIG. 1, an image capturing unit 64 for capturing an image of the workpiece held on the chuck table 20 to detect an area of the workpiece to be processed by the pulsed laser beam LB is also mounted on a lower surface of the distal end of the frame 36 at a position spaced from the condenser 42 along the X-axis.

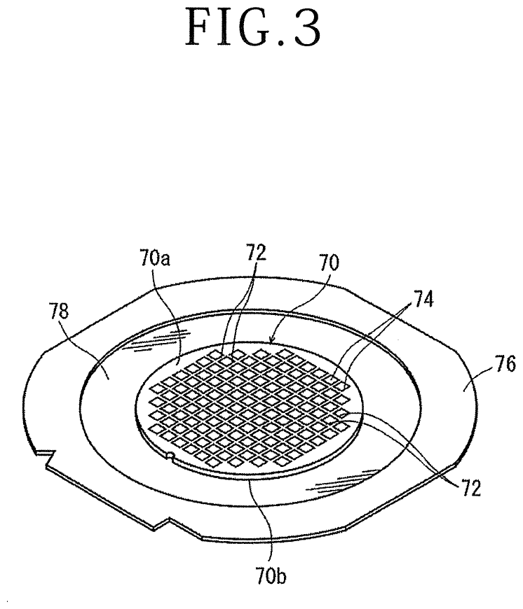

FIG. 3 depicts a disk-shaped wafer 70 as an example of the workpiece. The wafer 70 has a face side 70a demarcated by a grid of projected dicing lines 72 into a plurality of rectangular areas with respective devices 74 disposed therein. According to the present embodiment, the wafer 70 has a reverse side 70b stuck to an adhesive tape 78 whose peripheral edge is fixed to an annular frame 76.

For processing the wafer 70 as the workpiece along the projected dicing lines 72 on the laser processing apparatus 2, the wafer 70 with the face side 70a facing upwardly is attracted under suction to the upper surface of the suction chuck 22 of the chuck table 20, and the annular frame 76 has its outer peripheral edge secured in position by the clamps 24. Then, the image capturing unit 64 captures an image of the wafer 70 from above. Based on the image of the wafer 70 captured by the image capturing unit 64, the processing feed unit 8, the indexing feed unit 34, and the rotating unit move and rotate the chuck table 20 to orient those projected dicing lines 72 which extend in a first direction along the X-axis and position the condenser 42 above an end of one of those projected dicing lines 72. Then, the focused spot position adjusting means brings a focused spot into a required position on the projected dicing line 72. The pulsed laser beam LB is applied from the condenser 42 to the wafer 70 while the processing feed unit 8 is processing-feeding the chuck table 20 at a predetermined processing feed speed along the X-axis with respect to the focused spot.

When the pulsed laser beam LB is thus applied to the wafer 70 to process the wafer 70 along the projected dicing line 72, the focused spot may be positioned on the face side 70a of the wafer 70 and the pulsed laser beam LB may have a wavelength that is absorbable by the wafer 70 to perform an ablation process on the wafer 70. Upon arrival of the focused spot at the other end of the projected dicing line 72 after having performed the ablation process along the projected dicing line 72, the pulsed laser beam LB is turned off, and then the indexing feed unit 34 indexing-feeds the chuck table 20 along the Y-axis with respect to the focused spot by a distance corresponding to the interval between two adjacent projected dicing lines 72 extending in the first direction. Then, the pulsed laser beam LB is applied to the wafer 70 to process the wafer 70 along the next projected dicing line 72 extending in the first direction, performing the ablation process on the wafer 70 again. Thereafter, the indexing-feeding of the chuck table 20 and the ablation process are alternately repeated until the pulsed laser beam LB is applied to the wafer 70 along all the projected dicing lines 72 extending in the first direction. Then, the chuck table 20 is turned 90 degrees by the rotating unit, and the ablation process and the indexing-feeding of the chuck table 20 are alternately repeated until the pulsed laser beam LB is applied to the wafer 70 along all the projected dicing lines 72 extending in a second direction perpendicular to the first direction, thereby processing the wafer 70 with the pulsed laser beam LB along all the projected dicing lines 72 in the grid pattern.

When the pulsed laser beam LB is applied to the wafer 70, the polygon mirror motor rotates the polygon mirror 40 at a predetermined rotational speed to disperse the pulsed laser beam LB with the polygon mirror 40, and the dispersed region adjusting means 44 controls the dispersed region of the pulsed laser beam LB by causing the pulsed laser beam LB to follow the direction A in which the mirror facets M of the polygon mirror 40 are rotated. Specifically, when the pulsed laser beam LB is applied to the wafer 70, the control unit 56 detects an angular displacement of the polygon mirror 40 based on a light detection signal output from the light-detecting element 60 of the angular displacement detecting unit 54. Then, the control unit 56 determines a pattern for a voltage signal to be output to the AOD as the dispersed region adjusting means 44 based on the detected angular displacement of the polygon mirror 40. Then, the control unit 56 outputs a voltage signal to the dispersed region adjusting means 44 based on the determined pattern. In response to the voltage signal, the dispersed region adjusting means 44 adjusts the position where the pulsed laser beam LB falls on the polygon mirror 40 to control the dispersed region of the pulsed laser beam LB by causing the pulsed laser beam LB to follow the direction A in which the mirror facets M of the polygon mirror 40 are rotated in order that the pulsed laser beam LB remains applied to one mirror facet M for a predetermined period of time. After the pulsed laser beam LB has been applied to the mirror facet M for the predetermined period of time, the dispersed region adjusting means 44 repeatedly adjusts the position where the pulsed laser beam LB falls on the polygon mirror 40 in order that the pulsed laser beam LB remains applied to a next downstream mirror facet M with respect to the direction A for the predetermined period of time. The rotational speed of the polygon mirror 40 and the direction (along the X-axis or the Y-axis) in which the pulsed laser beam LB is dispersed can appropriately be determined depending on the wafer 70, i.e., the workpiece.

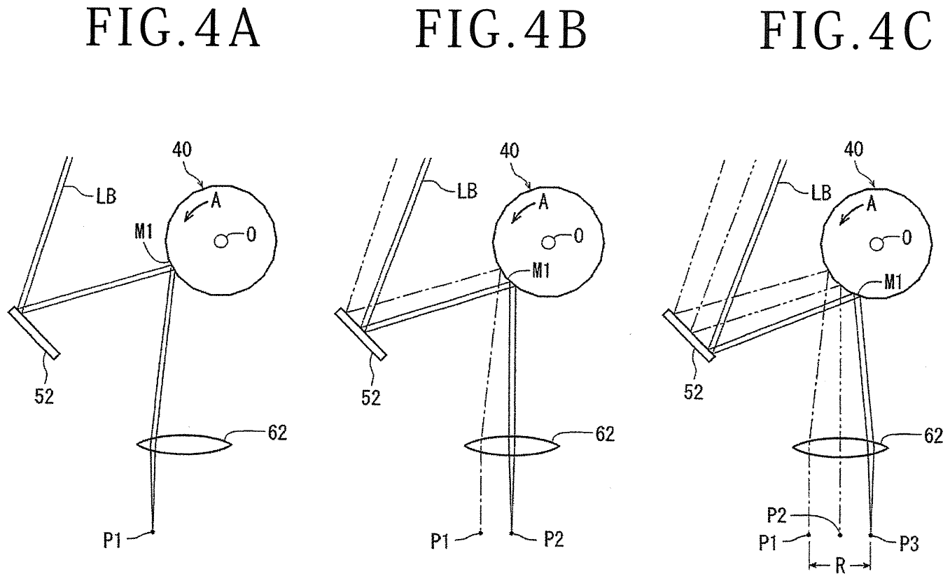

According to the present embodiment, as depicted in FIG. 4A, the dispersed region adjusting means 44 adjusts the position where the pulsed laser beam LB falls on the polygon mirror 40 in order that the pulsed laser beam LB is applied to a mirror facet M located at a given position, hereinafter referred to as “mirror facet Ml,” of the polygon mirror 40. The pulsed laser beam LB reflected by the mirror facet Ml is condensed by the fθ lens 62 of the condenser 42, and is applied to the wafer 70 at a position P1. FIG. 4B depicts the polygon mirror 40 that has turned 20 degrees in the direction A from the position depicted in FIG. 4A. According to the present embodiment, the dispersed region adjusting means 44 causes the pulsed laser beam LB to follow the direction A in which the mirror facets M of the polygon mirror 40 are rotated in order that the pulsed laser beam LB is applied to the mirror facet Ml as depicted in FIG. 4B. In FIG. 4B, the pulsed laser beam LB reflected by the mirror facet Ml is applied to the wafer 70 at a position P2. FIG. 4C depicts the polygon mirror 40 that has further turned 20 degrees in the direction A from the position depicted in FIG. 4B. According to the present embodiment, the dispersed region adjusting means 44 causes the pulsed laser beam LB to follow the direction A in which the mirror facets M of the polygon mirror 40 are rotated in order that the pulsed laser beam LB is still applied to the mirror facet Ml as depicted in FIG. 4C. In FIG. 4C, the pulsed laser beam LB reflected by the mirror facet Ml is applied to the wafer 70 at a position P3.

The trajectory of the pulsed laser beam LB that is indicated by the solid lines in FIG. 4A is indicated by the dot-and-dash lines in FIGS. 4B and 4C, and the trajectory of the pulsed laser beam LB that is indicated by the solid lines in FIG. 4B is indicated by the two-dot-and-dash lines in FIG. 4C. As can be understood from FIGS. 4A through 4C, the dispersed region adjusting means 44 causes the pulsed laser beam LB to follow the direction A in which the mirror facets M of the polygon mirror 40 are rotated, controlling the dispersed region, denoted by R in FIG. 4C, to extend from the position P1 to the position P3, in order that the pulsed laser beam LB is continuously applied to the mirror facet Ml while the polygon mirror 40 is rotating 40 degrees from the position depicted in FIG. 4A to the position depicted in FIG. 4C. When the pulsed laser beam LB has been applied to the mirror facet Ml for the predetermined period of time until the polygon mirror 40 reaches the angular position depicted in FIG. 4C, a mirror facet M that is two mirror facets downstream from the mirror facet Ml with respect to the direction A reaches the given position, i.e., the position taken by the mirror facet Ml in FIG. 4A, and the dispersed region adjusting means 44 adjusts the position where the pulsed laser beam LB falls on the polygon mirror 40 in order that the pulsed laser beam LB is applied to the mirror facet M in the given position for the predetermined period of time. The polygon mirror 40 repeatedly turns from the position depicted in FIG. 4A to the position depicted in FIG. 4C, applying the pulsed laser beam LB reflected by the mirror facet M to the wafer 70 in the dispersed region R from the position P1 to the position P3. Since the chuck table 20 that is holding the wafer 70 thereon is processing-fed along the X-axis by the processing feed unit 8 while the wafer 70 is being processed by the pulsed laser beam LB, as described above, the dispersed region R moves relatively to the wafer 70. The laser processing apparatus 2 can process the wafer 70 with the pulsed laser beam LB under the following processing conditions:

Wavelength of the pulsed laser beam LB: 355 nm

Repetitive frequency: 72 MHz

Average output power: 3 W

Polygon mirror diameter: 55 mm

Number of mirror facets: 18

Rotational speed of polygon mirror: 24000 rpm

If the pulsed laser beam LB is not caused to follow the direction A in which the mirror facets M rotate under the above processing conditions, then the number Pn of pulses of the pulsed laser beam LB dispersed by one mirror facet M is derived from the repetitive frequency F, the number Mn of mirror facets M of the polygon mirror 40, and the rotational speed N of the polygon mirror 40 as follows:

Pn=F/(Mn×N)=72 (MHz)/(18 mirror facets×24000 rpm)=72×10⁶ (1/second)/(18 mirror facets×400 (1/second))=10000 (pulses/mirror facet)

In case the pulsed laser beam LB is caused to follow the direction A in which the mirror facets M rotate under the above processing conditions, as described above, i.e., in case the pulsed laser beam LB is caused to follow one mirror facet M while the polygon mirror 40 is turning 40 degrees, and hence is applied to every other mirror facet M, the number Pn′ of pulses of the pulsed laser beam LB dispersed by one mirror facet M is 20000 (pulses/mirror facet), which is double the above Pn.

As described above, the laser beam applying unit 6 according to the present embodiment includes the laser oscillator 38 for emitting the pulsed laser beam LB, the polygon mirror 40 for dispersing the pulsed laser beam LB emitted from the laser oscillator 38, the condenser 42 for condensing the pulsed laser beam LB dispersed by the polygon mirror 40 and applying the condensed pulsed laser beam LB to the workpiece held on the chuck table 20 of the holding unit 4, and the dispersed region adjusting means 44 disposed between the laser oscillator 38 and the polygon mirror 40, for controlling the dispersed region R of the pulsed laser beam LB by causing the pulsed laser beam LB to follow the direction A in which the mirror facets M of the polygon mirror 40 are rotated. Therefore, the laser beam applying unit 6 can disperse the pulsed laser beam LB over an appropriate region depending on the workpiece, with the result that a processed quality depending on the workpiece can be achieved.

Generally, for increasing the rotational speed of a polygon mirror to increase the dispersing rate (scanning rate) of a pulsed laser beam, it is necessary to increase the number of mirror facets of the polygon mirror to make the outer peripheral shape of the polygon mirror closer to a true circle for thereby reducing the drag or air resistance exerted against the polygon mirror. An increase in the number of mirror facets results in a reduction of the central angle of each mirror facet, leading to a reduction in the dispersed region produced by each mirror facet. According to the present embodiment, as the pulsed laser beam LB is caused to follow the direction A in which the mirror facets M of the polygon mirror 40 are rotated, even if the number of mirror facets M is increased, the dispersed region R is prevented from decreasing by applying the pulsed laser beam LB to every other mirror facet M, i.e., applying the pulsed laser beam LB to one mirror facet M in an angular range doubling the central angle, and the drag or air resistance exerted against the polygon mirror 40 can be reduced by increasing the number of mirror facets M, with the result that the polygon mirror 40 can be rotated at a high speed. In other words, according to the present embodiment, the rotational speed of the polygon mirror 40 can be increased while preventing the dispersed region R from decreasing, for thereby increasing the dispersing rate (scanning rate) of the pulsed laser beam LB.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing method for processing a wafer with a laser beam using a laser processing apparatus, the laser processing apparatus including a holding unit for holding the workpiece thereon, a laser oscillator for emitting a pulsed laser beam, a polygon mirror for dispersing the pulsed laser beam emitted from the laser oscillator, a condenser for condensing the pulsed laser beam dispersed by the polygon mirror and applying the condensed pulsed laser beam to the workpiece held by the holding unit and dispersed region adjusting means for controlling a dispersed region of the pulsed laser beam, the laser processing method comprising:
a holding step of holding the workpiece on the holding unit; and
a processing step of processing the workpiece held by the holding unit by applying the pulsed laser beam
wherein, in the processing step, the dispersed region adjusting means controls the dispersed region of the pulsed laser beam by causing the pulsed laser beam to follow a direction in which the mirror facets of the polygon mirror are rotated.

2. The laser processing method according to claim 1, wherein the dispersed region adjusting means includes either one of an acousto-optic deflector, an electro-optic deflector, and a resonant scanner, and
wherein in the processing step, the dispersed region adjusting means adjusts the position where the pulsed laser beam falls on the polygon mirror to control the dispersed region of the pulsed laser beam by causing the pulsed laser beam to follow the direction in which the mirror facets of the polygon mirror are rotated.
